(19) United States
(12) Patent Application Publication
(10) Pub. No.: US 2019/0074211 A1
(43) Pub. Date: Mar. 7, 2019

(54) SEMICONDUCTOR DEVICE

(71) Applicant: SAMSUNG ELECTRONICS CO., LTD., Suwon-si (KR)

(72) Inventors: Kyung Seok MIN, Yongin-si (KR); Dong Kwon KIM, Suwon-si (KR); Cheol KIM, Hwaseong-si (KR); Young Mook OH, Hwaseong-si (KR); Jeong Yun LEE, Yongin-si (KR); Hyun Ho JUNG, Seoul (KR)

(21) Appl. No.: 15/962,059

(22) Filed: Apr. 25, 2018

(30) Foreign Application Priority Data
Sep. 4, 2017 (KR) 10-2017-0112669

(51) Int. Cl. H01L 21/762; H01L 21/8234

(52) U.S. Cl. CPC H01L 21/76232; H01L 29/785; H01L 21/823481

(57) ABSTRACT

A semiconductor device includes a substrate having an active pattern extending in a first direction, a first gate structure and a second gate structure extending in a second direction, intersecting the first direction, to traverse the active pattern, the first gate structure and the second gate structure isolated from each other while facing each other in the second direction, a gate isolation pattern disposed between the first gate structure and the second gate structure, the gate isolation pattern having a void, and a filling insulating portion positioned lower than upper surfaces of the first gate structure and the second gate structure within the gate isolation pattern, the filling insulating portion being connected to at least an upper end of the void.

### CROSS-REFERENCE TO RELATED APPLICATION

Korean Patent Application No. 10-2017-0112669, filed on Sep. 4, 2017, in the Korean Intellectual Property Office, and entitled: “Semiconductor Device,” is incorporated by reference herein in its entirety.

### BACKGROUND

### 1. Field

Embodiments relate to a semiconductor device and a method of manufacturing the same.

### 2. Description of the Related Art

As demand for high performance, high speed, and/or multifunctionality in semiconductor devices has increased, a degree of integration of semiconductor devices has increased. Semiconductor devices having micropatterns correspond to a trend for a high degree of integration.

### SUMMARY

Embodiments are directed to a semiconductor device that may include: a substrate having an active pattern extending in a first direction; a first gate structure and a second gate structure extending in a second direction, intersecting the first direction, to traverse the active pattern, the first gate structure and the second gate structure isolated from each other while facing each other in the second direction; a gate isolation pattern disposed between the first gate structure and the second gate structure, the gate isolation pattern having a void; and a filling insulating portion positioned lower than upper surfaces of the first gate structure and the second gate structure in the gate isolation pattern, the filling insulating portion being connected to at least an upper end of the void.

Embodiments are also directed to a semiconductor device that may include: a first gate structure and a second gate structure extending in one direction, the first gate structure and the second gate structure being isolated from each other; an interlayer insulating film disposed around the first gate structure and the second gate structure, the interlayer insulating film including a first insulating material; a gate isolation pattern disposed between the first gate structure and the second gate structure, the gate isolation pattern including a second insulating material different from the first insulating material; and a filling insulating portion positioned within the gate isolation pattern, the filling insulating portion extending nonlinearly in a thickness direction of the first gate structure and the second gate structure between the first gate structure and the second gate structure.

Embodiments are also directed to a semiconductor device that may include: a substrate having an active pattern extending in a first direction; a plurality of pairs of gate structures extending in a second direction, intersecting the first direction, to traverse the active pattern, each of the pairs of the plurality of pairs of gate structures having a first gate structure and a second gate structure isolated from each other while facing each other in the second direction; a gate isolation pattern extending between the first gate structure and the second gate structure of each of the pairs of gate structures, the gate isolation pattern having a void between the first gate structure and the second gate structure of at least one pair of the plurality of pairs of gate structures; and a filling insulating portion positioned lower than upper surfaces of the plurality of pairs of gate structures within the gate isolation pattern, the filling insulating portion being connected to at least an upper end of the void.

### BRIEF DESCRIPTION OF DRAWINGS

Features will become apparent to those of skill in the art by describing in detail exemplary embodiments with reference to the attached drawings in which:

FIG. 1 illustrates a plan view of a semiconductor device, according to an example embodiment;

FIGS. 2 through 5 illustrate cross-sectional views taken along lines I-I′, II-IP, and IV-IV′ of FIG. 1, respectively;

FIGS. 6 and 7 illustrate cross-sectional views taken along lines II-II′ and IV-IV′ of FIG. 1, respectively;

FIGS. 8 through 10 illustrate cross-sectional views of gate isolation patterns employable in semiconductor devices, according to various example embodiments;

FIGS. 11A through 20A illustrate cross-sectional views of stages in a method of manufacturing a semiconductor device, according to example embodiments, taken along line II-IP of FIG. 1;

FIGS. 11B through 20B illustrate cross-sectional views of stages in a method of manufacturing a semiconductor device, according to example embodiments, taken along line IV-IV′ of FIG. 1;

FIGS. 21A through 24A illustrate cross-sectional views of stages in a method of manufacturing a semiconductor device, according to example embodiments, taken along line II-II′ of FIG. 1; and

FIGS. 21B through 24B illustrate cross-sectional views of stages in a method of manufacturing a semiconductor device, according to example embodiments, taken along line IV-IV′ of FIG. 1.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. In the drawing figures, the dimensions of layers and regions may be exaggerated for clarity of illustration. Like reference numerals refer to like elements throughout.

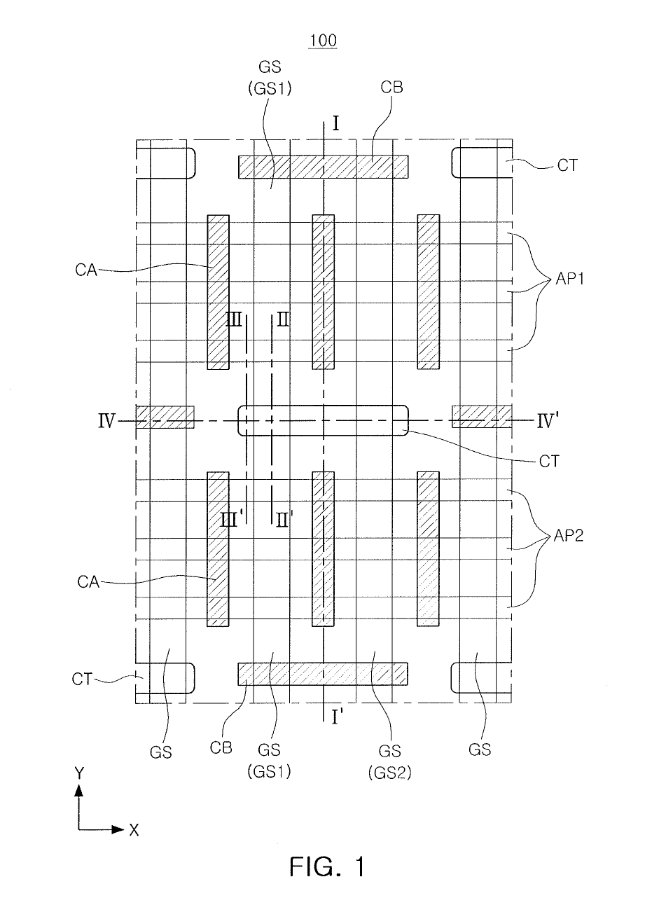

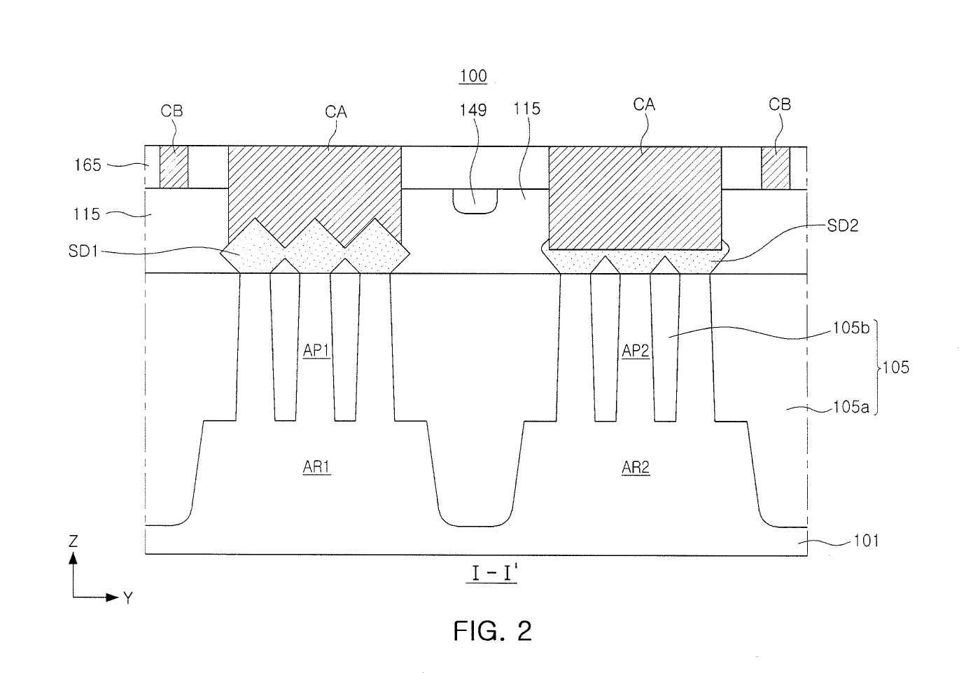

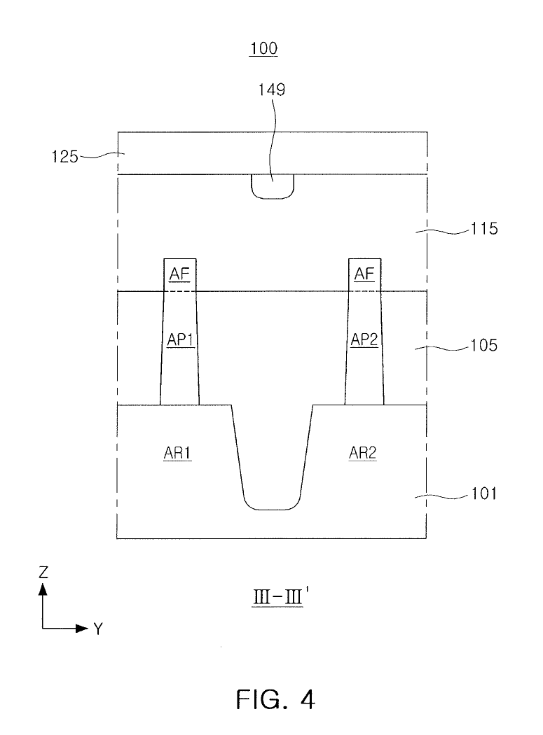

FIG. 1 is a plan view of a semiconductor device, according to an example embodiment. FIGS. 2 through 5 are cross-sectional views taken along lines I-I′, and IV-IV′ of FIG. 1, respectively.

Referring to FIGS. 1 through 5, a semiconductor device 100 according to an example embodiment may include a substrate 101, and a device isolation film 105 disposed on the substrate 101 to define a first active region AR1 and a second active region AR2.

The substrate 101 may be, for example, a silicon substrate, a germanium substrate, or a silicon on insulator (SOI) substrate. An example is not limited thereto. In the present example embodiment, the first active region AR1 may be an n-type well for a P-channel metal oxide semiconductor (PMOS) transistor, and the second active region AR2 may be a p-type well for an N-channel metal oxide semiconductor (NMOS) transistor.

First and second active patterns AP1 and AP2 may be provided on the first and second active regions AR1 and AR2, respectively. The first and second active patterns AP1 and AP2 may extend in a first direction X, and may be arranged in a second direction Y, intersecting the first direction X. The first and second active patterns AP1 and AP2 may be provided as an active region of a transistor. In the present example embodiment, each of the first and second active patterns AP1 and AP2 may be provided in the first and second active regions AR1 and AR2, respectively, as three active patterns, but an example is not limited thereto. In another example embodiment, each of the first and second active patterns AP1 and AP2 may be provided as a single active pattern or a different number of active patterns.

Referring to FIG. 2, the device isolation film 105 may include a first isolation part 105a defining the first and second active regions AR1 and AR2, and a second isolation part 105b defining the first and second active patterns AP1 and AP2. For example, the device isolation film 105 may include a silicon oxide or a silicon oxide-based insulating material. The first isolation part 105a may have a bottom surface deeper than that of the second isolation part 105b.

The first isolation part 105a may also be referred to as deep trench isolation (DTI), and the second isolation part 105b may also be referred to as shallow trench isolation (STI).

The second isolation part 105b may be disposed on the first and second active regions AR1 and AR2, and each of the first and second active patterns AP1 and AP2 may have an upper region (hereinafter, referred to as an “active fin (AF)”) exposed by the second isolation part 105b. As described above, levels of upper surfaces of the first and second active patterns AP1 and AP2 may be higher than that of an upper surface of the device isolation film 105. However, an example is not limited thereto. In some example embodiments, the upper surfaces of the first and second active patterns AP1 and AP2 may be substantially coplanar with the upper surface of the device isolation film 105.

Gate structures GS may be provided to traverse the first and second active patterns AP1 and AP2. Each of the gate structures GS may extend in the second direction Y, and may be arranged in the first direction X.

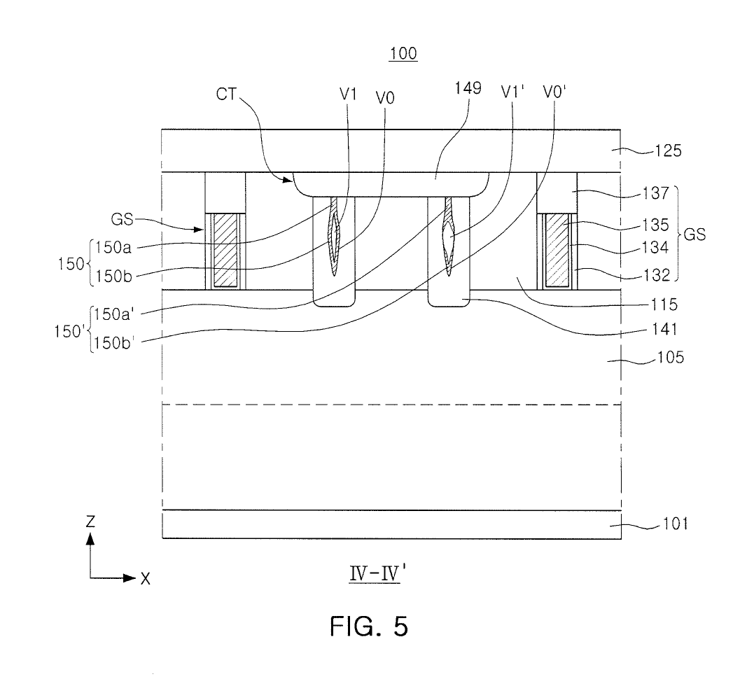

As illustrated in FIG. 5, the gate structure GS may include sidewall spacers 132, and a gate insulating film 134 and a gate electrode 135 disposed between the sidewall spacers 132. The gate structure GS employed in the present example embodiment may include a gate capping layer 137 disposed on the gate insulating film 134 and on the gate electrode 135. After forming layers for the gate insulating film 134 and the gate electrode 135, the gate capping layer 137 may be formed in a region of a gate region in which a portion of the layers may be etched back. For example, the gate capping layer 137 may be formed of an insulating material, such as a silicon nitride.

As illustrated in FIG. 1, a gate isolation pattern CT may be provided to isolate at least one of the gate structures GS in the second direction Y. The gate isolation pattern CT may divide the gate structure GS into first and second gate structures GS1 and GS2.

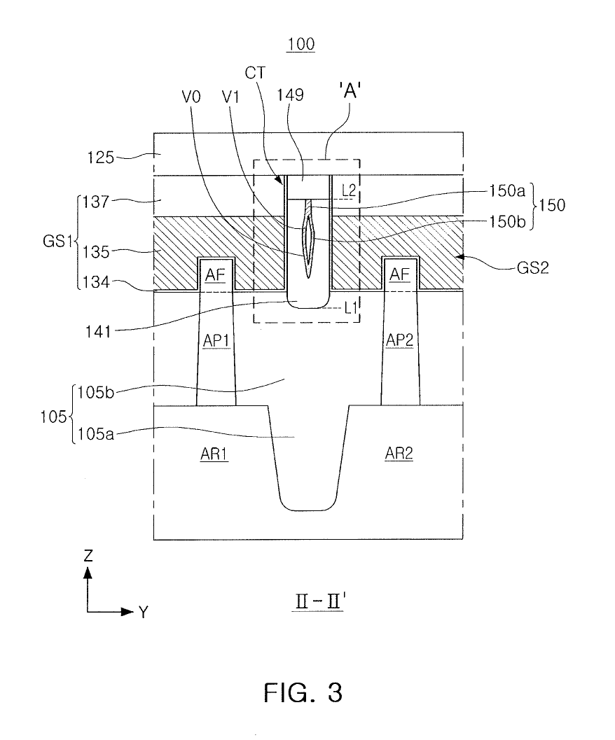

As illustrated in FIGS. 1 and 3, the first and second gate structures GS1 and GS2 isolated from each other may be arranged to face each other in an extension direction thereof, for example, in the second direction Y. As in the present example embodiment, the gate isolation pattern CT may be disposed in a region between the first and second gate structures GS1 and GS2, and may extend in the first direction X. Accordingly, a plurality of gate structures GS, for example, two gate structures GS, may be isolated in the second direction Y. In some example embodiments, the gate isolation pattern CT may only isolate a single gate structure GS.

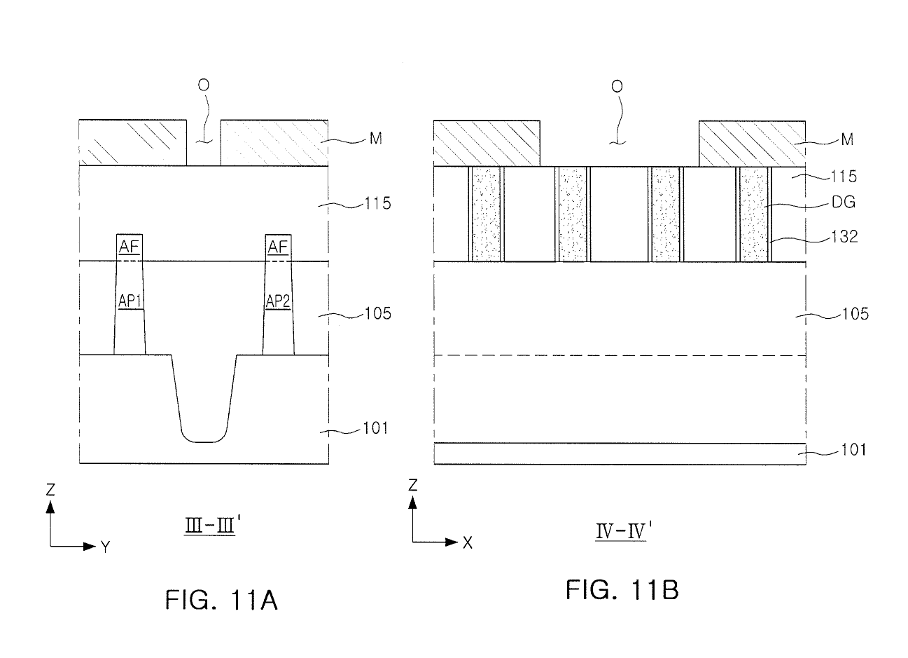

The gate isolation pattern CT may include an insulating structure positioned between the first and second gate structures GS1 and GS2. The gate isolation pattern CT may be formed prior to completing the gate structure GS. For example, prior to performing a replacement process for forming the gate structure GS, the gate isolation pattern CT may be formed by removing a sacrificial layer portion (for example, polysilicon) positioned in the gate isolation region and then filling the gate isolation region with an insulating material (refer to FIGS. 11B through 22B). The term “gate isolation region,” or “isolation region,” may be used to specify a trench region from which a sacrificial layer positioned between the first and second gate structures GS1 and GS2 may be removed.

Referring to FIG. 3, the gate isolation pattern CT employed in the present example embodiment may include a void V0. The void V0 may be a portion that is not filled in the process of filling the gate isolation region with an insulating material when filling a trench for gate isolation and a recess with an isolation insulating layer. The void V0 may have a shape extending in a thickness direction t of the first and second gate structures GS1 and GS2.

A filling insulating portion 150 may be formed to be connected to at least an upper end of the void V0. The filling insulating portion 150 may be provided to fill an opened upper end of the void V0. The filling insulating portion 150 may include a first region 150a filling the upper end of the void V0, and a second region 150b disposed on an internal surface of the void V0. The second region 150b may extend from the first region 150a to be formed on the internal surface of the void V0.

As illustrated in FIG. 3, the filling insulating portion 150 may not entirely fill the void V0. In this case, a remaining void V1 may be present. In a final structure, only the remaining void V1 may be observed as an empty region, and the original void V0 may be displayed as an outline of the filling insulating portion 150. In the present application, for ease of description, a void prior to forming the filling insulating portion 150 may be referred to as the “void” V0, and a void after forming the filling insulating portion 150, confirmed in the final structure, may be referred to as the “remaining void” V1.

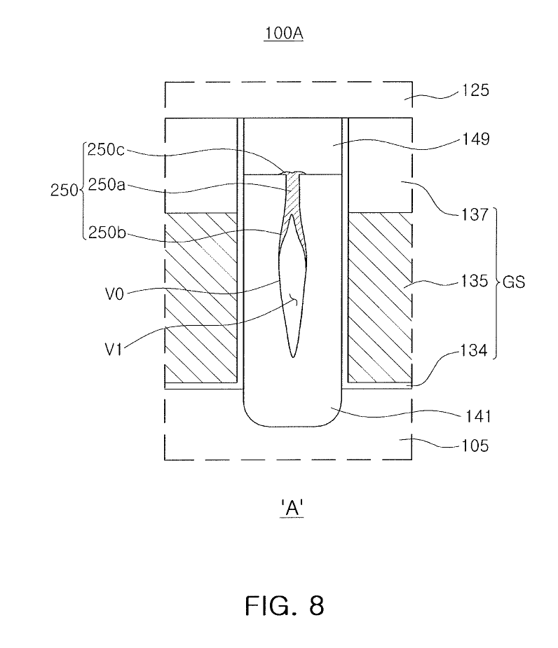

The filling insulating portion 150 may have various shapes and structures, and accordingly, the shape of the remaining void V1 may also be variously changed. For example, as illustrated in FIG. 5, because a second region 150b′ of the filling insulating portion 150′ is isolated from a first region 150a′ thereof, a filling insulating portion 150′ provided in another void V0′ may only be formed on a portion of an internal surface of the other void V0′. Even when applied to the same processes, the voids V0 and V0′ may have an irregular structure. According to such conditions, the shape and structure of the filling insulating portion 150 or 150′ may also be diversified. This will be described in more detail with reference to FIGS. 8 through 10.

Referring to FIG. 3, the gate isolation pattern CT may include a first insulating portion 141 positioned between the first and second gate structures GS1 and GS2, and a second insulating portion 149 disposed on the first insulating portion 141.

The first insulating portion 141 may be an actual isolation means for the first and second gate structures GS1 and GS2, and may only be formed in the gate isolation region. In contrast, the second insulating portion 149 may extend in the first direction X, and may expand to a first interlayer insulating film 115 (hereinafter, also referred to as an “interlayer insulating film”) disposed around the first and second gate structures GS1 and GS2. The gate isolation pattern CT employed in the present example embodiment may be associated with two gate structures GS.

As illustrated in FIG. 5, the second insulating portion 149 may be connected to two gate isolation regions, for example, two first insulating portions 141, adjacent to the second insulating portion 149. As described above, the gate isolation pattern CT employed in the present example embodiment may be a gate isolation pattern associated with a plurality of pairs of gate structures GS. As illustrated in FIGS. 1 and 5, the gate isolation pattern CT may have an elongated structure extending in the first direction X.

Thus, the gate isolation pattern CT may include a plurality of first insulating portions 141 positioned between the respective pairs of gate structures GS, and a second insulating portion 149 disposed on the first insulating portions 141 and having a portion extending in the first direction X to connect the first insulating portions 141. In another example embodiment, the gate isolation pattern CT may also have a single first insulating portion 141 dividing a single gate structure.

In some example embodiments, the second insulating portion 149 may be formed of a first insulating material the same as or similar to that of the first interlayer insulating film 115, and the first insulating portion 141 may be formed of a second insulating material different from the first insulating material. For example, the first insulating material may be formed of a silicon oxide or a silicon oxide-based material, and the second insulating material may be formed of an insulating material, such as SiOCN, SiON, SiCN, or SiN.

In some example embodiments, the filling insulating portion 150 or 150′ may be formed of the second insulating material, similar to the first insulating portion 141. For example, the filling insulating portion 150 or 150′ may be formed of SiOCN, SiON, SiCN, or SiN. Even when a material the same as that of the first insulating portion 141 is used as the filling insulating portion 150 or 150′, the filling insulating portions 150 and 150′ may be formed by a different process, thus being distinguished from each other. For example, the first insulating portion 141 and the filling insulating portion 150 or 150′ may be formed of a silicon nitride, the first insulating portion 141 may be formed by a vapor deposition process, such as a chemical vapor deposition (CVD) or physical vapor deposition (PVD) process, while the filling insulating portion 150 or 150′ may be formed by an atomic layer deposition (ALD) process. In a final product, the filling insulating portion 150 or 150′ may be a film that is denser than the first insulating portion 141.

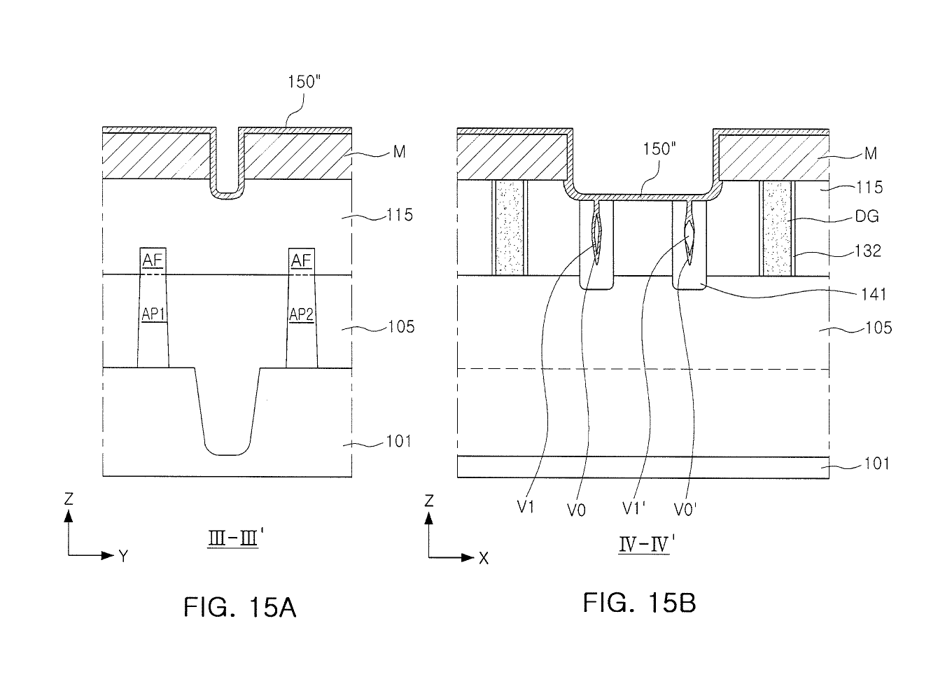

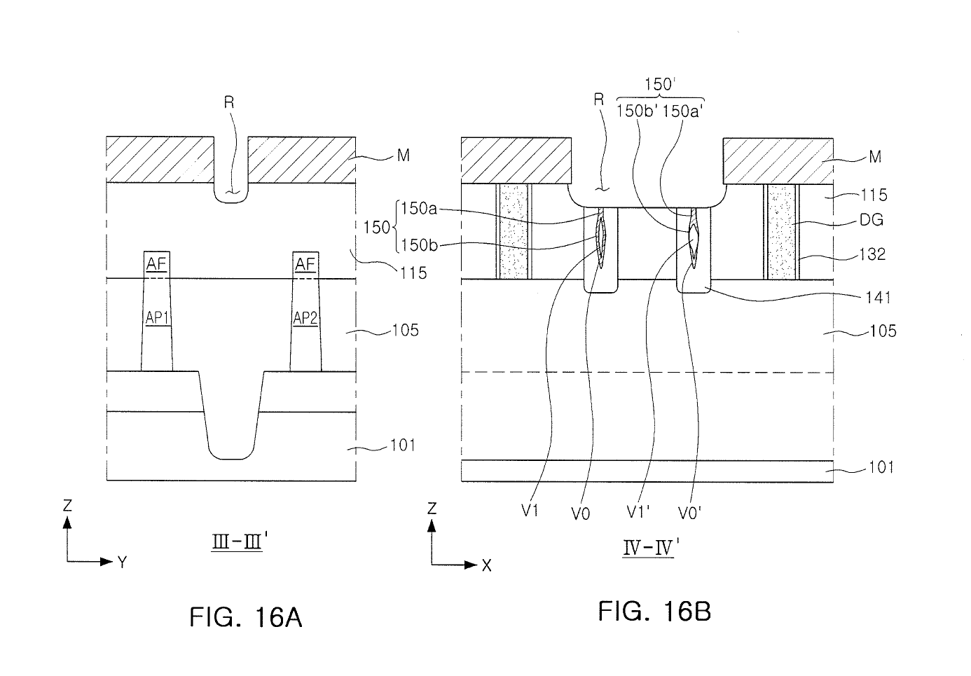

Referring to FIGS. 3 and 5, a level L2 of an upper end of the filling insulating portion 150 may be substantially the same as that of an upper surface of the first insulating portion 141 (refer to FIGS. 15B and 16B). Thus, the level L2 of the upper end of the filling insulating portion 150 may be lower than those of upper surfaces of the first and second gate structures GS1 and GS2.

When each of the first and second gate structures GS1 and GS2 includes the gate capping layer 137, the upper end of the filling insulating portion 150 may be higher than an upper surface of the gate electrode 135 and lower than an upper surface of the gate capping layer 137.

The filling insulating portions 150 and 150′ may be used to close the opened void V0 and V0′, and, when viewed in plane, each of the first region 150a of the filling insulating portion 150 and the first region 150a′ of the filling insulating portion 150′ may be surrounded by the first insulating portion 141.

In the present example embodiment, the second insulating portion 149 may expand to the first interlayer insulating film 115. At an interface between the second insulating portion 149 and the first interlayer insulating film 115, the first insulating material (for example, a silicon nitride) the same as that of the first insulating portion 141 may not be substantially present. In the process of forming the first insulating portion 141, the first insulating material (for example, SiN) remaining on a surface of the first interlayer insulating film 115 may be entirely removed, which may help prevent an occurrence of defects in a following growth process.

The gate isolation pattern CT may be disposed on the device isolation film 105. For example, the gate structure GS may be divided into the first gate structures GS1 associated with a p-type metal-oxide-semiconductor field-effect transistor (MOSFET) and the second gate structure GS2 associated with an n-type MOSFET. In the present example embodiment, a lower region of the gate isolation pattern CT may be positioned within the device isolation film 105. As illustrated in FIGS. 3 and 5, a level L1 of a lower surface of the gate isolation pattern CT may be lower than that of the top surface of the device isolation film 105. In another example embodiment, the level L1 of the lower surface of the gate isolation pattern CT may be lower than that of a lower surface of the gate structure GS.

Referring to FIG. 3, the gate insulating film 134 may be disposed between the gate electrode 135 and the first and second active patterns AP1 and AP2 and between the gate electrode 135 and the device isolation film 105. Further, the gate insulating film 134 may extend between the gate electrode 135 and the sidewall spacers 132 (refer to FIG. 5). In the present example embodiment, the gate insulating film 134 may further extend between the gate electrode 135 and a side wall of the gate isolation pattern CT. For example, the sidewall spacers 132 may be formed of an insulating material, such as SiOCN, SiON, SiCN, or SiN, and the gate insulating film 134 may include a silicon oxide film, a silicon oxynitride film, or may include a high-k film, having a dielectric constant higher than that of a silicon oxide.

First and second source/drain regions SD1 and SD2 may be provided on the first and second active patterns AP1 and AP2 on both sides of the gate structure GS, respectively. As illustrated in FIG. 2, the first and second source/drain regions SD1 and SD2 may be epitaxial layers re-grown using the first and second active patterns AP1 and AP2 as seeds. As an example, the first source/drain regions SD1 may include silicon germanium (SiGe) doped with p-type impurities to provide a p-type MOSFET. Further, the second source/drain regions SD2 may include silicon (Si) and/or silicon carbide (SiC) doped with n-type impurities. The first and second source/drain regions SD1 and SD2 may have different shapes along a crystallographically stable surface during a growth process. As illustrated in FIG. 2, a cross section of the first source/drain region SD1 may have a pentagonal shape, and a cross section of the second source/drain region SD2 may be a hexagonal shape, or a polygonal shape having a gentle angle.

Referring to FIG. 2, the first interlayer insulating film 115 may be disposed around the first and second gate structures GS1 and GS2 to cover the first and second source/drain regions SD1 and SD2. A second interlayer insulating film 125 may be formed on the first interlayer insulating film 115. Similar to the first interlayer insulating film 115, the second interlayer insulating film 125 may be formed of a silicon oxide or a silicon oxide-based material.

Referring to FIGS. 1 and 2, first contacts CA may be provided between the gate structures GS. The first contacts CA may be connected to the first and second source/drain regions SD1 and SD2 through the first interlayer insulating film 115 and the second interlayer insulating film 125. As in the present example embodiment, the first contacts CA may be connected to a plurality of source/drain regions in the second direction Y. However, an example is not limited thereto.

Each of second contacts CB may be electrically connected to the gate electrode 135 through the second interlayer insulating film 125. As in the present example embodiment, the second contact CB may extend in the first direction X to connect to a plurality of gate electrodes. However, an example is not limited thereto. For example, the first and second contacts CA and CB may be formed of tungsten (W), cobalt (Co), titanium (Ti), alloys thereof, or combinations thereof.

In addition, wirings electrically connected to the first contacts CA and the second contacts CB may be provided. The wirings may apply a voltage to each of the first and second source/drain regions SD1 and SD2 and the gate electrodes 135 through the first contacts CA and the second contacts CB.

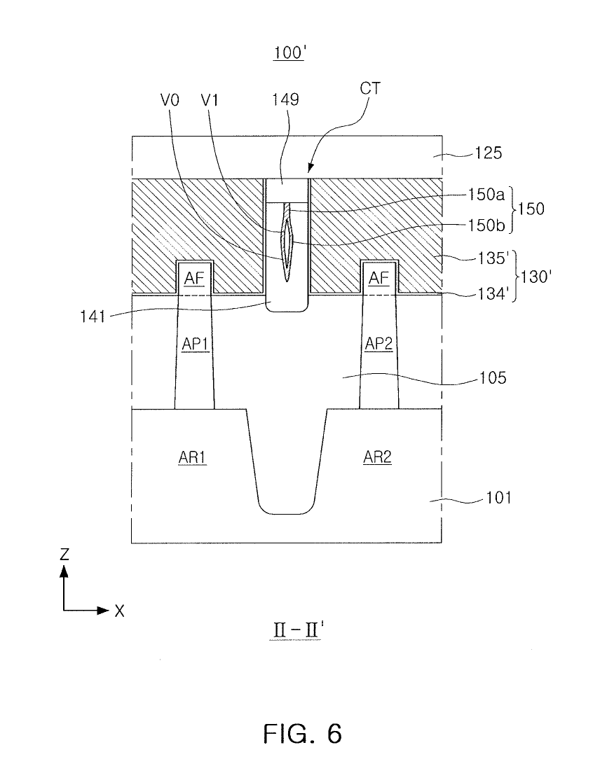

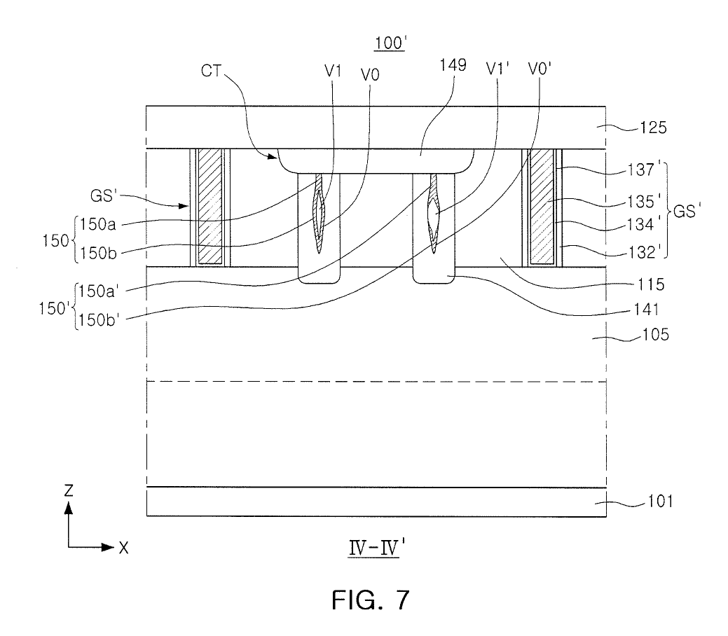

The gate isolation pattern CT according to the present example embodiment may also be applied to a semiconductor device having a different structure. For example, the gate isolation pattern CT may be applied to a gate structure having a different structure. FIGS. 6 and 7 illustrate a semiconductor device with a gate structure having a different structure, and may be understood as being cross-sectional views taken along lines II-II′ and IV-IV′ of FIG. 1, respectively.

Referring to FIGS. 6 and 7, a semiconductor device 100′ according to the present example embodiment may include a gate structure GS' having sidewall spacers 132′, a gate insulating film 134′ disposed between the sidewall spacers 132′, and a gate electrode 135′. The semiconductor device 100′ according to the present example embodiment may not include the gate capping layer 137 of FIG. 5, unlike in the foregoing example embodiment. In this case, an upper end of a filling insulating portion 150 or 150′ may be lower than an upper surface of the gate electrode 135′.

As described above, in the different structure of the semiconductor device 100′, relative positions of the filling insulating portions 150 and 150′ and the voids V0 and V0′ may be changed to a certain degree. However, the filling insulating portions 150 and 150′ may be positioned within the first insulating portion 141 positioned in the gate isolation pattern CT, particularly, a gate isolation region, and the filling insulating portions 150 and 150′ may be connected to at least upper ends of the voids V0 and V0′.

FIGS. 8 through 10 are cross-sectional views of gate isolation patterns employable in semiconductor devices, according to various example embodiments, and may be understood as being enlarged views of region A of the semiconductor device illustrated in FIG. 3.

Referring to FIG. 8, a semiconductor device 100A may include a void V0 and a filling insulating portion 250 formed in a thickness direction of the gate structure GS.

The filling insulating portion 250 may include a first region 250a filling an upper end of the void V0 to close the void V0, and a second region 250b extending along a portion of an internal surface of the void V0. In the present example embodiment, the void V0 may be rapidly closed in the process of forming the filling insulating portion 250 due to a narrow open region of the void V0, so that the filling insulating portion 250 may only be deposited on the periphery of an upper region of the void V0 and may not substantially be deposited in a lower region of the void V0. Thus, a remaining void V1 may be present.

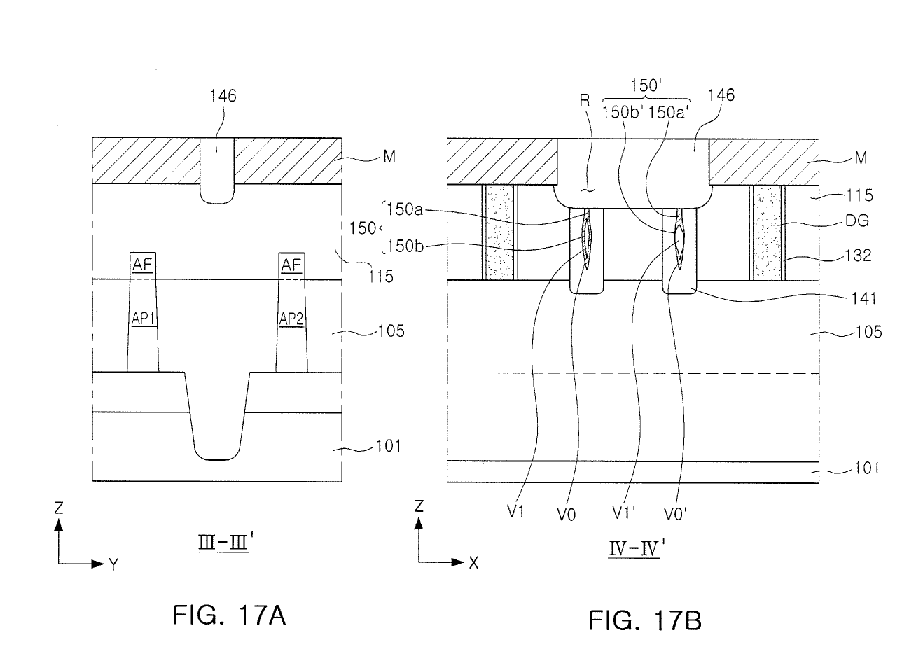

Further, the filling insulating portion 250 employed in the present example embodiment may have a third region 250c remaining on a portion of an upper surface of the first insulating portion 141. In the process of forming the filling insulating portion 250, a portion thereof not associated with the void may be removed (refer to FIGS. 16B and 17B), but may remain while not being entirely removed, and may provide the third region 250c positioned on the upper surface of the first insulating portion 141.

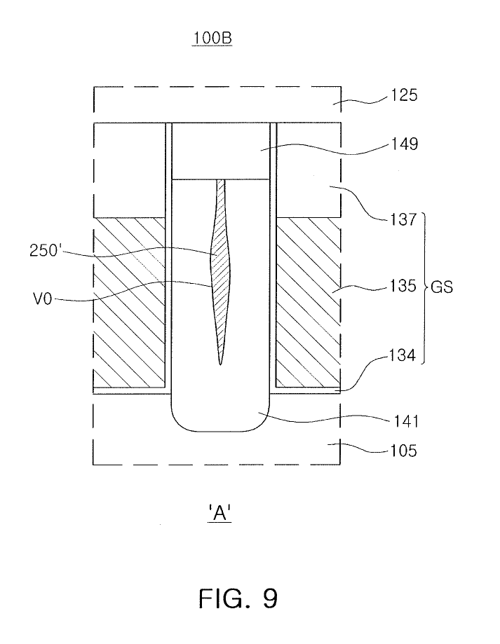

Referring to FIG. 9, a semiconductor device 100B may include a filling insulating portion 250′ substantially filling a void V0.

As in the present example embodiment, the filling insulating portion 250′ may entirely fill an internal space of a void V0 using a deposition material having excellent step coverage. In this case, a remaining void may not substantially be present or may remain in an extremely small amount.

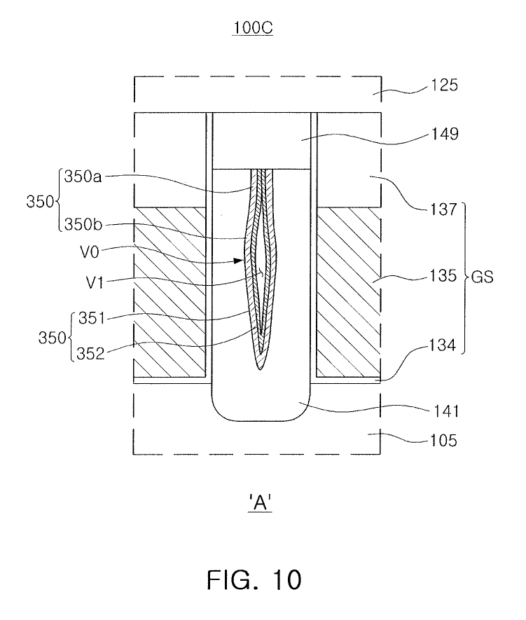

Referring to FIG. 10, a semiconductor device 100C may include a filling insulating portion 350 having multiple layers.

The filling insulating portion 350 employed in the present example embodiment may include first and second insulating films 351 and 352 formed of different materials. For example, the first insulating film 351 may be formed of SiON, SiOCN, or SiO₂ having a relatively good step coverage, and the second insulating film 352 may be formed of a silicon nitride for preventing a void V0 from being exposed in terms of selection ratio in a subsequent process. According to the present example embodiment, use of two or more layers having different properties may allow the void V0 to be filled, which may help prevent the void V0 from being opened in a subsequent process, as well as reducing the amount of a remaining void V1. The filling insulating portion 350 is not limited to a double layer, and may include three or more layers. For example, the filling insulating portion 350 may also have a triple-layer structure of SiOCN, SiO₂, and Si₃N₄.

The filling insulating portion 350 formed in the manner described above may include a first region 350a filling an upper end of the void V0 to close the void V0, and a second region 350b extending along a portion of an internal surface of the void V0.

Various structures and characteristics of the above-described filling insulating portions may be combined in different ways. For example, the third region 250c illustrated in FIG. 8 may be combined with the filling insulating portion 250′ or 350 illustrated in FIG. 9 or 10, so that a region of the filling insulating portion 250′ or 350 may have a portion extending from the upper surface of the first insulating portion 141. Further, the filling insulating portion 350 illustrated in FIG. 10 may also be provided, such that the void V0 may be substantially entirely filled, as illustrated in FIG. 9.

FIGS. 11A through 20A are cross-sectional views illustrating a method of manufacturing a semiconductor device, according to example embodiments, taken along line II-II′ of FIG. 1. FIGS. 11B through 20B are cross-sectional views illustrating a method of manufacturing a semiconductor device, according to example embodiments, taken along line IV-IV′ of FIG. 1.

The manufacturing method according to the present example embodiment may be understood as being the method of manufacturing a semiconductor device described above with reference to FIGS. 1 through 5, identical or like reference numerals may be provided for substantially the same configurations, and a redundant description will be omitted for simplicity of explanation.

Referring to FIGS. 11A and 11B, sidewall spacers 132 and a sacrificial layer DG may be formed in a region for forming a gate structure, and a mask pattern M for gate isolation may be formed.

The sacrificial layer DG may be disposed between the sidewall spacers 132. The sacrificial layer DG may be formed of, for example, polysilicon. The mask pattern M may be formed on a first interlayer insulating film 115, and may have an opening O for defining a gate isolation region of the sacrificial layer DG. For example, the mask pattern M may be formed of a hard mask material, such as SiN or TEOS. The gate isolation region of the sacrificial layer DG exposed in a subsequent process may be removed.

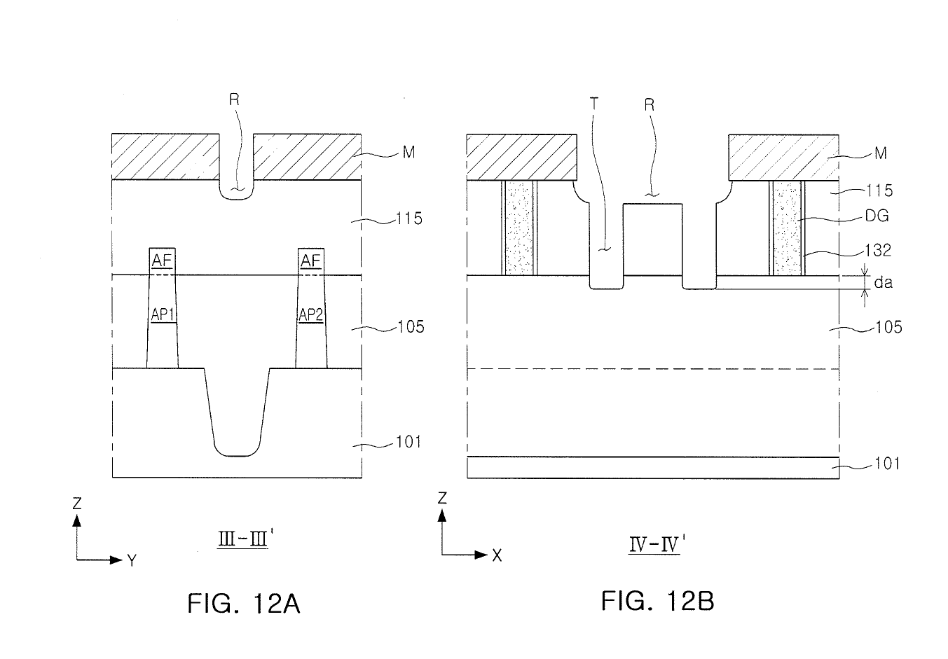

Referring to FIGS. 12A and 12B, the exposed gate isolation region of the sacrificial layer DG exposed using the mask pattern M as an etching mask may be removed.

By the etching process, a recess R of the first interlayer insulating film 115 may be formed along with a trench T for gate isolation. When viewed in plane, the recess R of the first interlayer insulating film 115 may have the same shape as the gate isolation pattern CT illustrated in FIG. 1.

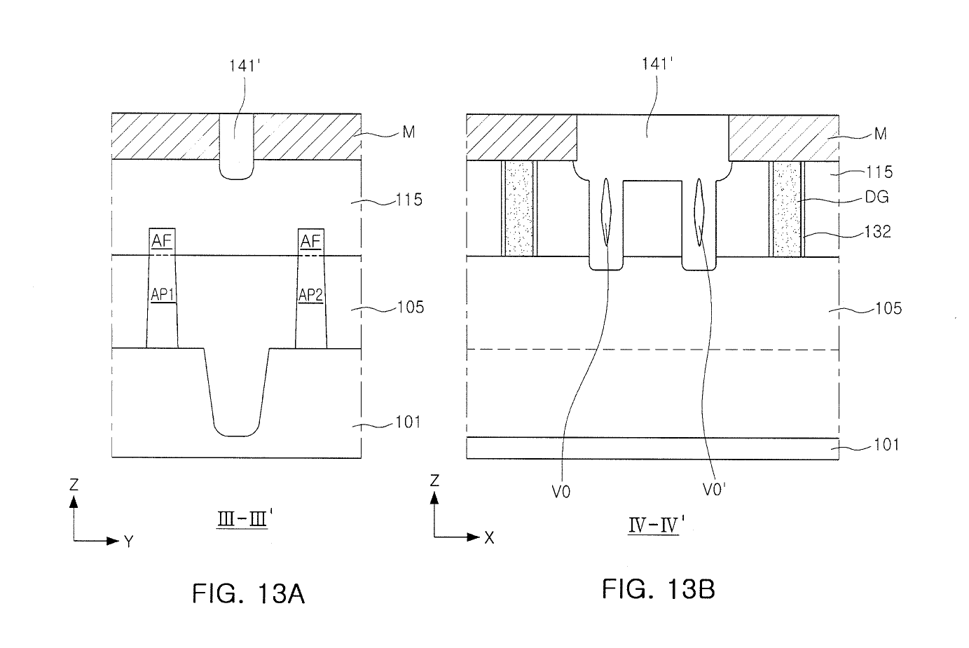

Referring to FIGS. 13A and 13B, an isolation insulating layer 141′ may be formed to form a first insulating portion 141 (refer to FIG. 5).

The trench T for gate isolation and the recess R may be filled with the isolation insulating layer 141′. In the filling process, voids V0 and V0′ may be generated in the trench T for gate isolation. The isolation insulating layer 141′ may be formed of an insulating material, such as SiOCN, SiON, SiCN, SiN, or the like. In the present example embodiment, the isolation insulating layer 141′ may be formed of a silicon nitride. The isolation insulating layer 141′ may be formed by a deposition process, such as a CVD or PVD process, and may have an upper surface planarized by a chemical mechanical polishing (CMP) process.

The filling process may be replaced with a process of depositing a relatively thin film. In place of not entirely filling the recess R, an additional CMP process may be omitted by depositing a thin film sufficient to only fill the trench T for gate isolation. A void may be generated even in the thin film deposition process, and a void having a relatively greater width than the voids V0 and V0′ formed in the filling process may be formed.

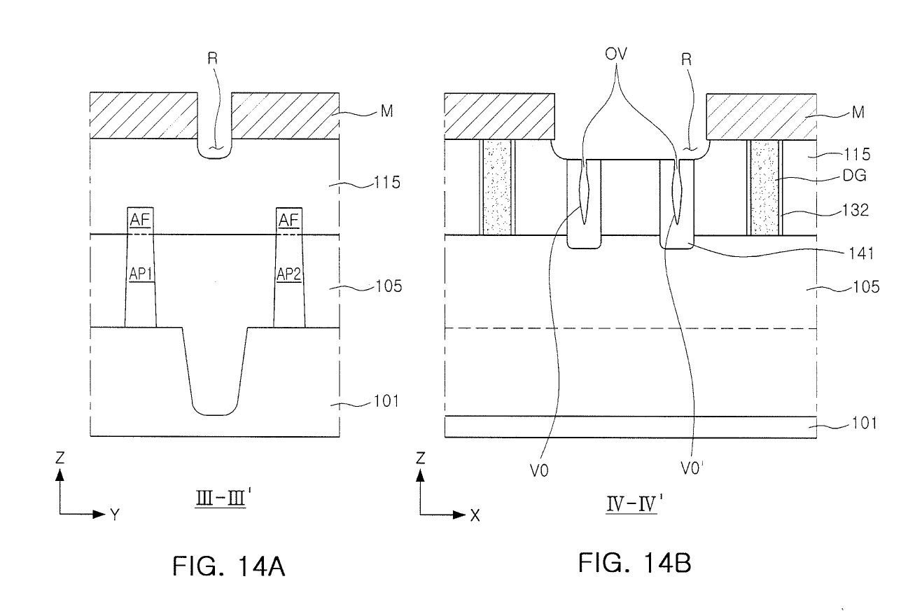

Referring to FIGS. 14A and 14B, a first chamfering process may be performed to remove a portion of the isolation insulating layer 141′ positioned within the recess R.

In the first chamfering process, a first insulating portion 141 for gate isolation may be provided by removing the portion of the isolation insulating layer 141′ positioned within the recess R and leaving a portion of the isolation insulating layer 141′ positioned within the trench T for gate isolation. The portion of the isolation insulating layer 141′ positioned within the recess R may be removed through etching, so as not to remain therewithin. Thus, a material of the isolation insulating layer 141′ may not remain on a surface of the first interlayer insulating film 115, which may help avoid defects in a subsequent process. The chamfering process may expose the voids V0 and V0′ positioned within the first insulating portion 141. As illustrated in FIG. 14B, the voids V0 and V0′ may have an opening OV exposed to an upper surface of the first insulating portion 141.

Referring to FIGS. 15A and 15B, a filling insulating film 150″ may be formed after the first chamfering process.

In the present example process, the opening OV of the voids V0 and V0′ may be closed by the filling insulating film 150″. The filling insulating film 150″ may be formed by an ALD process. For example, similar to the first insulating portion 141, the filling insulating film 150″ may be formed of an insulating material, such as SiOCN, SiON, SiCN, SiN, or the like. Even when formed of a material the same as or similar to that of the first insulating portion 141, the filling insulating film 150″ may be formed as a denser film by the ALD process, so that the filling insulating film 150″ may be distinguished from the first insulating portion 141 in a final structure.

Referring to FIGS. 16A and 16B, a second chamfering process may be performed to remove a portion of the filling insulating film 150″ positioned within the recess R.

In the second chamfering process, the portion of the filling insulating film 150″ positioned within the recess R may be removed, and portions of the filling insulating film 150″ positioned within the voids V0 and V0′ may remain, to thus provide filling insulating portions 150 and 150′. The filling insulating portion 150 may include a first region 150a disposed on an upper end of the void V0, and a second region 150b extending to an internal surface of the void V0. The filling insulating portion 150′ may include a first region 150a′ disposed on an upper end of the void V0′, and a second region 150b′ extending to an internal surface of the void V0′. The openings OV of the voids V0 and V0′ may be closed using the first regions 150a and 150a′ of the filling insulating portions 150 and 150′, respectively. Thus, defects caused by opening the voids V0 and V0′ may be prevented from occurring in a subsequent process.

Referring to FIGS. 17A and 17B, prior to removal of the mask pattern M, the recess R may be filled with an insulating material 146. The insulating material 146 used in this process is not limited thereto, and may be, for example, a spin-on glass, such as Tonen silazane (TOSZ).

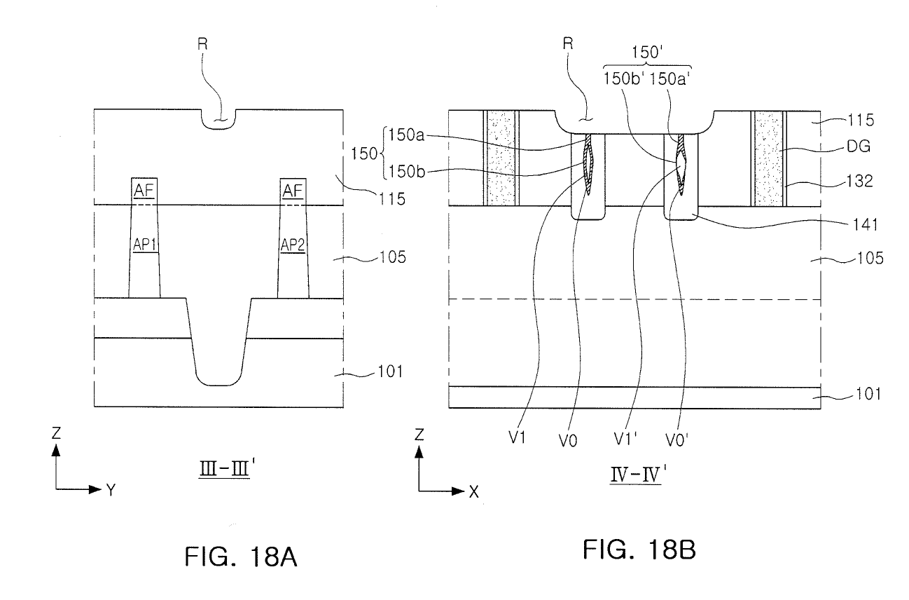

Subsequently, as illustrated in FIGS. 18A and 18B, the mask pattern M may be removed, and the sacrificial layer DG in a gate region may be exposed to perform a replacement process for forming a gate structure. The process of removing the mask pattern M may be performed by, for example a CMP process after the process of forming the insulating material 146.

Subsequently, the insulating material 146 in the recess R may be removed using, for example, a chemical oxide removal (COR) process. In addition, an etchback process for a silicon nitride forming a hard mask may be performed. Then etchback process may remove a nitride (for example, a residue, such as the filling insulating film 150″ or the like) remaining on a surface of the first interlayer insulating film 115 exposed to the recess R. Thus, defects caused by the remaining nitride may be effectively prevented in a subsequent process.

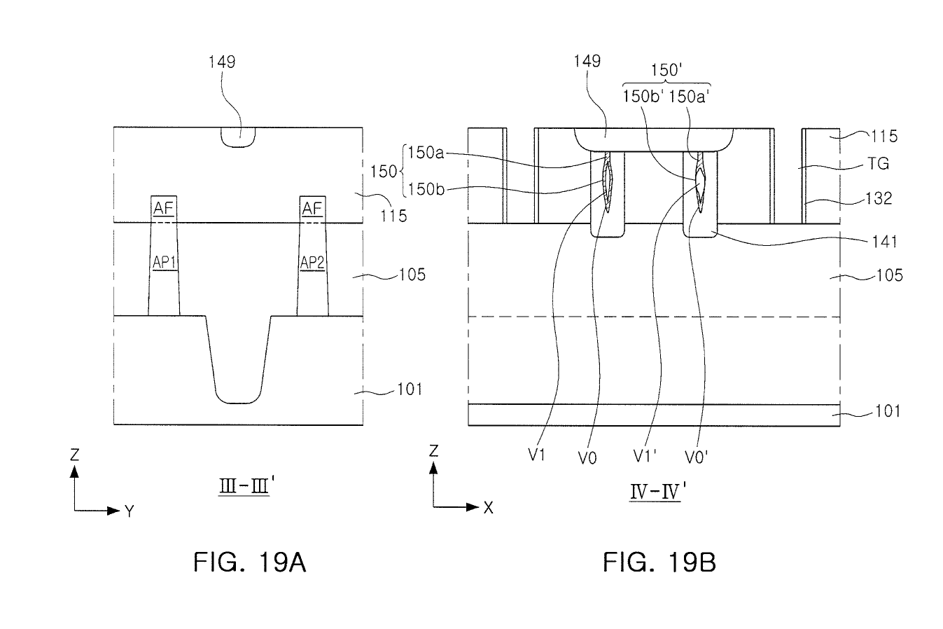

Referring to FIGS. 19A and 19B, a second insulating portion 149 may be formed in the recess R, and the sacrificial layer DG in the gate region may be removed.

The second insulating pattern 149 may be formed of a material the same as or similar to that of the first interlayer insulating film 115. For example, the second insulating portion 149 may be formed of a silicon oxide or a silicon oxide-based material. Even when the material the same as or similar to that of the first interlayer insulating film 115 is used, the boundary between the second insulating portion 149 and the first interlayer insulating film 115 may be identified. This may be a result of a difference between process and formation conditions.

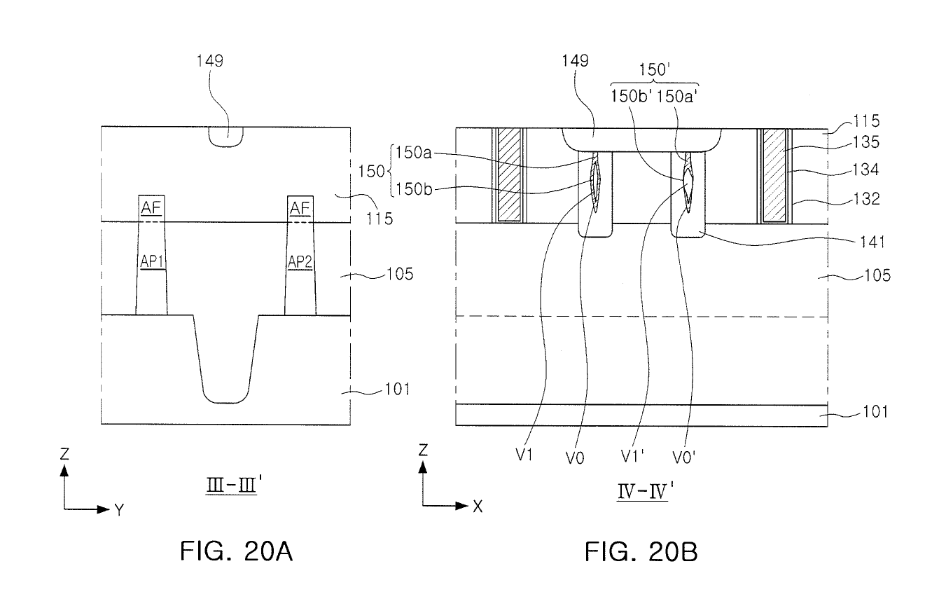

After removing the sacrificial layer DG in the gate region, a gate insulating film 134 and a gate electrode 135 may be formed in the trench T for gate isolation, as illustrated in FIGS. 20A and 20B. The gate insulating film 134 and the gate electrode 135 may be deposited, such that the gate insulating film 134 and the gate electrode 135 may be positioned between the sidewall spacers 132, and then a gate structure GS may be formed through, for example, a CMP process to have an upper surface coplanar with that of the first interlayer insulating film 115. For example, the gate insulating film 134 may include a high-k film including a silicon oxide film or a silicon oxynitride film or having a higher dielectric constant than a silicon oxide, and the gate electrode 135 may include a metal, a metal nitride, or doped polysilicon.

In addition, as following processes for obtaining a semiconductor device of FIGS. 1 through 5, an etchback process for the gate structure, a gate capping layer formation process, and processes for the first and second contacts.

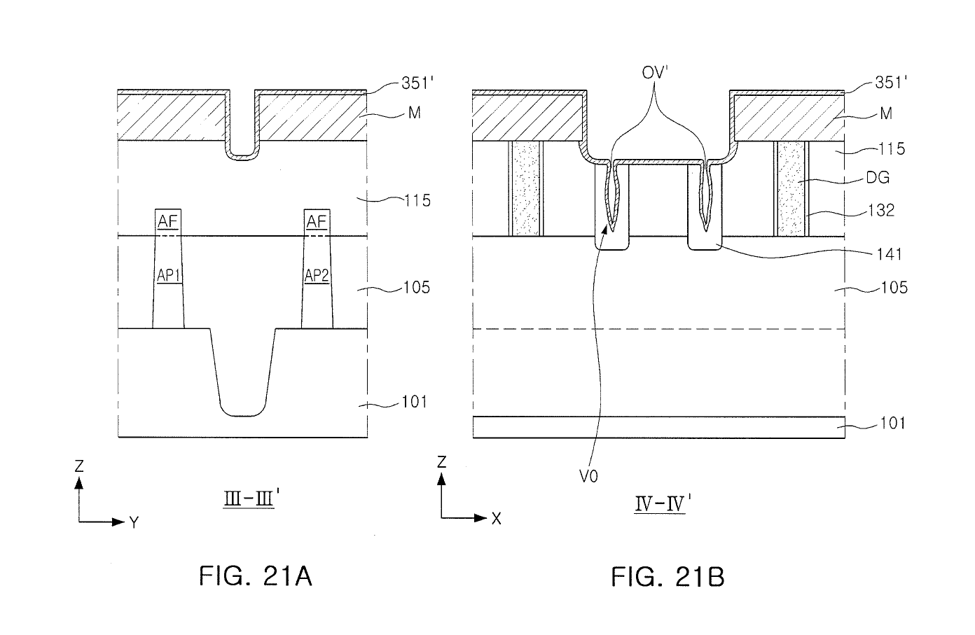

FIGS. 21A through 24A are cross-sectional views illustrating a method of manufacturing a semiconductor device, according to example embodiments, taken along line II-IP of FIG. 1. FIGS. 21B through 24B are cross-sectional views illustrating a method of manufacturing a semiconductor device, according to example embodiments, taken along line IV-IV′ of FIG. 1.

Processes, illustrated in FIGS. 11A through 14B, of the manufacturing method, according to the foregoing example embodiment, may be understood as being processes preceding the processes illustrated in FIGS. 21A through 21B. The present example embodiment may be usefully applied to the voids V0 and V0′ having a size relatively greater than that of the voids V0 and V0′ of FIG. 13B formed in the foregoing example embodiment.

Referring to FIGS. 21A and 21B, a first filling insulating film 351′ may be formed after the first chamfering process.

In the present process, the first filling insulating film 351′ may be formed to fill internal spaces of the void V0 and a void V0′. In the present process, the first filling insulating film 351′ may be formed of an insulating material, such as SiOCN, SiON, or SiO₂, having a relatively good step coverage, to significantly reduce openings OV′ of the voids V0 and V0′. However, the openings OV′ of the voids V0 and V0′ may not yet be closed.

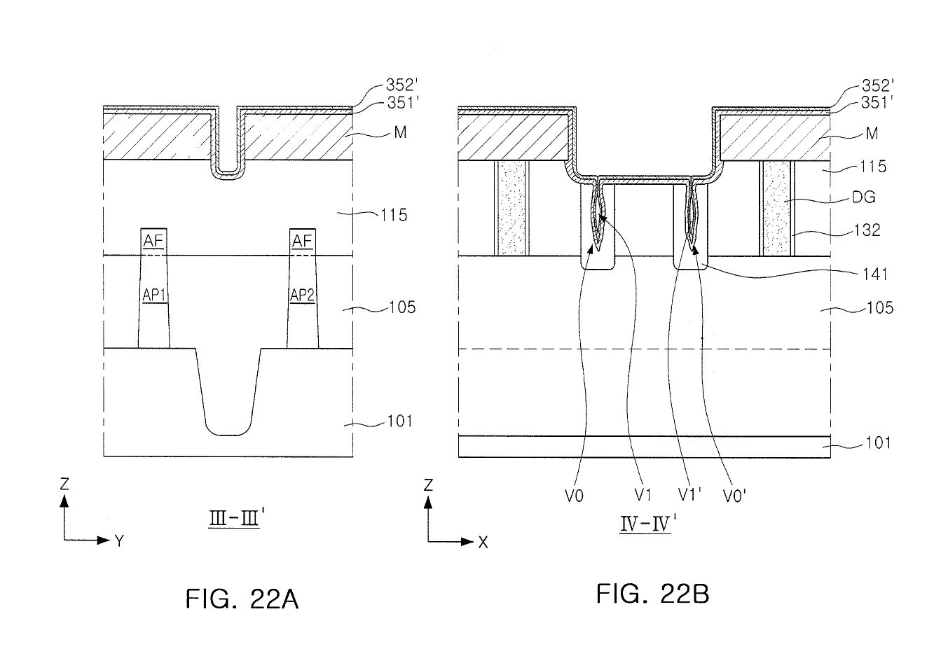

Subsequently, as illustrated in FIGS. 22A and 22B, a second filling insulating film 352′ may be formed.

In the present process, the openings OV′ of the voids V0 and V0′ may be closed by the second filling insulating film 352′. The second filling insulating film 352′ may be formed of, for example, a silicon nitride for preventing the voids V0 and V0′ from being exposed in terms of selection ratio in a subsequent process. The second filling insulating film 352′ may be formed by, for example, an ALD process. The double layer according to the present example embodiment may include two or more different filling insulating films 351′ and 352′ formed of, for example, SiON or Si₃N₄, so that the double layer may be readily identified in a final structure. Further, such a double layer may effectively cover a relatively large void.

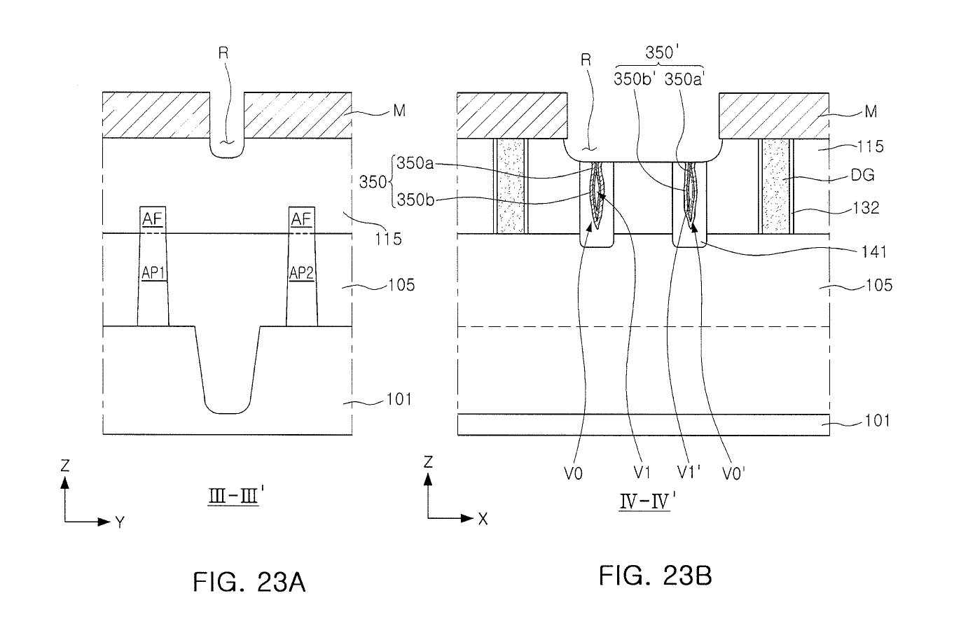

Referring to FIGS. 23A and 23B, a second chamfering process may be performed to remove portions 351′ and 352′ (FIGS. 22A and 22B) of the first and second filling insulating films positioned within the recess R.

In the second chamfering process, the portions of the first and second filling insulating films 351′ and 352′ positioned within the recess R may be removed, and portions of the first and second filling insulating films 351′ and 352′ positioned within the voids V0 and V0′ may remain, to thus provide filling insulating films 350 and 350′. The filling insulating film 350 may include the first region 350a disposed on an upper end of the void V0, and the second region 350b extending to an internal surface of the void V0. The filling insulating film 350′ may include a first region 350a′ disposed on an upper end of the void V0′, and a second region 350b′ extending to an internal surface of the void V0′. The first region 350a of the filling insulating film 350 may effectively close the opening OV of the void V0, and the first region 350a′ of the filling insulating film 350′ may effectively close the opening OV of the void V0. As a result, defects caused by opening the voids V0 and V0′ may be prevented from occurring in a subsequent process.

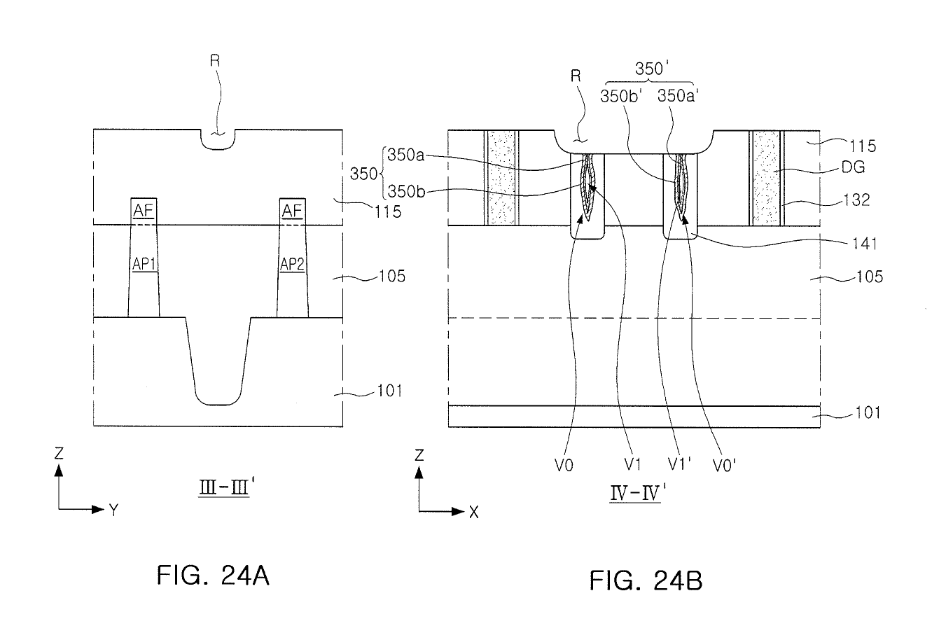

Referring to FIGS. 24A and 24B, the mask pattern M may be removed, and the sacrificial layer DG in a gate region may be exposed to perform a replacement process for forming a gate structure.

The process of removing the mask pattern M may be performed by a CMP process after filling the recess R with an insulating material. The processes performed with reference to FIGS. 17 and 18 may be referenced as the detailed description of the present process.

Subsequently, a gate capping layer formation process and processes for the first and second contacts may be performed along with the gate structure formation process, illustrated in FIGS. 19 and 20, of the manufacturing method, according to the foregoing example embodiment.

By way of summation and review, when semiconductor devices having micropatterns corresponding to a trend for a high degree of integration thereof are manufactured, the micropatterns may be implemented to have a microwidth or a microdistance. Further, in an advance beyond planar metal-oxide-semiconductor field-effect transistors (MOSFETs), consideration has been given to semiconductor devices including fin field effect transistors (FinFETs), including a channel having a three-dimensional structure.

As set forth above, according to example embodiments, there may be provided a semiconductor device that may prevent an occurrence of defects in a subsequent process by avoiding a void from being exposed, while entirely removing an insulating film, such that the insulating film may not remain on an undesired surface of a recess, and a method of manufacturing the semiconductor device. Example embodiments may provide a semiconductor device having an improved degree of integration and a method of manufacturing the same.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a substrate having an active pattern, the active pattern extending in a first direction;
a first gate structure and a second gate structure extending in a second direction, intersecting the first direction, to traverse the active pattern, the first gate structure and the second gate structure isolated from each other while facing each other in the second direction;
a gate isolation pattern disposed between the first gate structure and the second gate structure, the gate isolation pattern having a void; and
a filling insulating portion positioned lower than upper surfaces of the first gate structure and the second gate structure in the gate isolation pattern, the filling insulating portion being connected to at least an upper end of the void.

2. The semiconductor device as claimed in claim 1, wherein the void has a shape extending in a thickness direction of the first gate structure and the second gate structure.

3. The semiconductor device as claimed in claim 1, wherein the filling insulating portion is further disposed on at least a region of an internal surface of the void.

4. The semiconductor device as claimed in claim 3, wherein the filling insulating portion extends along the internal surface of the void.

5. The semiconductor device as claimed in claim 1, wherein the filling insulating portion substantially entirely fills an internal space of the void.

6. The semiconductor device as claimed in claim 1, wherein the filling insulating portion includes at least two insulating films formed of different materials.

7. The semiconductor device as claimed in claim 1, wherein the gate isolation pattern has a lower surface positioned lower than lower surfaces of the first gate structure and the second gate structure.

8. The semiconductor device as claimed in claim 1, further comprising: an interlayer insulating film disposed around the first gate structure and the second gate structure,
wherein the gate isolation pattern includes:
a first insulating portion positioned between the first gate structure and the second gate structure, the first insulating portion having an upper surface on which an upper end of the filling insulating portion is positioned; and
a second insulating portion disposed on the first insulating portion, the second insulating portion extending in the first direction to expand to the interlayer insulating film.

9. The semiconductor device as claimed in claim 8, wherein, at an interface between the second insulating portion and the interlayer insulating film, an insulating material the same as an insulating material of the first insulating portion is not substantially present.

10. The semiconductor device as claimed in claim 1, wherein the first gate structure and the second gate structure each include a gate electrode and a gate capping layer disposed on the gate electrode.

11. The semiconductor device as claimed in claim 10, wherein an upper end of the filling insulating portion is higher than an upper surface of the gate electrode and lower than an upper surface of the gate capping layer.

12. The semiconductor device as claimed in claim 1, further comprising: an device isolation film defining an active region in which the active pattern is positioned,
wherein the gate isolation pattern is positioned on the device isolation film.

13. A semiconductor device, comprising:
a first gate structure and a second gate structure extending in one direction, the first gate structure and the second gate structure being isolated from each other;
an interlayer insulating film disposed around the first gate structure and the second gate structure, the interlayer insulating film including a first insulating material;
a gate isolation pattern disposed between the first gate structure and the second gate structure, the gate isolation pattern including a second insulating material different from the first insulating material; and
a filling insulating portion positioned within the gate isolation pattern, the filling insulating portion extending nonlinearly in a thickness direction of the first gate structure and the second gate structure between the first gate structure and the second gate structure.

14. The semiconductor device as claimed in claim 13, wherein the gate isolation pattern includes a remaining void below the filling insulating portion.

15. The semiconductor device as claimed in claim 13, wherein the gate isolation pattern includes a remaining void surrounded by the filling insulating portion.

16. A semiconductor device, comprising:
a substrate having an active pattern extending in a first direction;
a plurality of pairs of gate structures extending in a second direction, intersecting the first direction, to traverse the active pattern, each pair of the plurality of pairs of gate structures having a first gate structure and a second gate structure isolated from each other while facing each other in the second direction;
a gate isolation pattern extending between a first gate structure and a second gate structure of each of the pairs of gate structures, the gate isolation pattern having a void between the first gate structure and the second gate structure of at least one pair of the plurality of pairs of gate structures; and a filling insulating portion positioned lower than upper surfaces of the plurality of pairs of gate structures within the gate isolation pattern, the filling insulating portion being connected to at least an upper end of the void.

17. The semiconductor device of claim 16, further comprising: an interlayer insulating film disposed around the plurality of pairs of gate structures, the interlayer insulating film being formed of a first insulating material,
wherein the gate isolation pattern includes:
a plurality of first insulating portions between respective pairs of gate structures, the plurality of first insulating portions being formed of a second insulating material; and
a second insulating portion on the plurality of first insulating portions, the second insulating portion having a portion extending in the second direction, intersecting the first direction, to connect the plurality of first insulating portions.

18. The semiconductor device as claimed in claim 17, wherein the void includes a plurality of voids respectively disposed between the first gate structure and the second gate structure of each of two or more pairs of the plurality of pairs of gate structures, the plurality of voids having different shapes.

19. The semiconductor device as claimed in claim 18, wherein at least one of the plurality of voids has an internal surface to which a corresponding filling insulating portion extends.

20. The semiconductor device as claimed in claim 18, wherein at least one of the plurality of voids has an internal surface filled with a corresponding filling insulating portion.
